(19) United States
(12) Patent Application Publication
(10) Pub. No.: US 2024/0105248 A1
(43) Pub. Date: Mar. 28, 2024

(54) TCAM WITH HYSTERETIC OXIDE MEMORY CELLS

(71) Applicant: Intel Corporation, Santa Clara, CA (US)

(72) Inventors: Abhishek Anil Sharma, Portland, OR (US); Tahir Ghani, Portland, OR (US); Sagar Suthram, Portland, OR (US); Anand Murthy, Portland, OR (US); Wilfred Gomes, Portland, OR (US); Pushkar Ranade, San Jose, CA (US)

(73) Assignee: Intel Corporation, Santa Clara, CA (US)

(21) Appl. No.: 17/955,194

(22) Filed: Sep. 28, 2022

(51) Int. Cl. G11C 11/22; H01L 27/11587; H01L 27/1159; H01L 29/66; H01L 29/78

(52) U.S. Cl. CPC G11C 11/2275; H01L 27/11587; H01L 27/1159; H01L 29/6684; H01L 29/78391

(57) ABSTRACT

An integrated circuit (IC) die includes a substrate and an array of memory cells formed in or on the substrate with a memory cell of the array of memory cells that includes a storage circuit that comprises a hysteretic-oxide material. A ternary content-addressable memory (TCAM) may utilize hysteretic-oxide memory cells. Other embodiments are disclosed and claimed.

### BACKGROUND

There is an ongoing need for improved computational devices to enable ever increasing demand for modeling complex systems, providing reduced computation times, and other considerations. In some contexts, scaling features of integrated circuits has been a driving force for such improvements. Other advancements have been made in materials, device structure, circuit layout, and so on. In particular, there is an ongoing desire to improve memory structures that are included in or otherwise support operation of integrated circuits. It is with respect to these and other considerations that the present improvements have been needed. Such improvements may become critical as the desire to improve computational efficiency become even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIG. 1A illustrates a block diagram plan view of an example integrated circuit (IC) die;

FIG. 1B illustrates a block diagram of an example of a system;

FIG. 1C illustrates a block diagram of another example of a system;

FIG. 2 illustrates a block diagram of an example of ternary content-addressable memory (TCAM);

FIG. 3A illustrates a circuit diagram of an example of a two ferroelectric field effect transistor (two FeFET) hysteric-oxide memory cell (HOMC);

FIG. 3B is a graph of an example of gate voltage versus drain current for the HOMC of FIG. 3A;

FIG. 3C is a table of an example voltages for a write operation for the HOMC of FIG. 3A;

FIG. 3D is a table of an example voltages for a search operation for the HOMC of FIG. 3A;

FIG. 3E is a time-aligned graph of an example gate voltage and drain current for a write operation for the HOMC of FIG. 3A;

FIG. 4 illustrates a circuit diagram of an example of a TCAM array;

FIGS. 5A to 5B illustrate cross sectional side views of an example IC die with a HOMC with a shared contact;

FIG. 6A illustrates a partial, perspective views of another example IC die that includes two or more tiers of TCAM arrays of two-FeFET HOMCs;

FIG. 6B is an exploded, partial, perspective view of an area 6B in FIG. 6A;

FIG. 7 illustrates a cross-sectional view of a low-temperature, IC system using die- and package-level active cooling, that includes HOMCs;

FIG. 8 illustrates a view of an example two-phase immersion cooling system for low-temperature operation of an IC die;

FIGS. 9A to 9B illustrates various processes or methods for forming HOMCs on an IC die;

FIG. 10 illustrates a diagram of an example data server machine employing an IC die with HOMCs; and

FIG. 11 is a block diagram of an example computing device, all in accordance with at least some implementations of the present disclosure.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure. The term “aligned” (i.e., vertically or laterally) indicates at least a portion of the components are aligned in the pertinent direction while “fully aligned” indicates an entirety of the components are aligned in the pertinent direction.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified, the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking, or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve memory structures, particularly with respect to ternary content-addressable memory (TCAM) structures. Conventional TCAM typically utilizes random access memory (RAM), such as dynamic RAM (DRAM) or static RAM (SRAM)-like memory cells. A typical transistor structure for an integrated circuit (IC) may involve a contact structure followed by a gate structure followed by another contact structure (contact-gate-contact). In a memory array, a space may be provided between two transistors (e.g., contact-gate-contact followed by some space followed by another contact-gate-contact), which consumes area on the IC. At room temperature, smaller circuit structures may exhibit problematic resistance. At room temperature, thermal noise and/or thermal excitation may be problematic for voltage distributions of storage circuits. Some embodiments may overcome one or more of the foregoing problems.

Some embodiments may utilize hysteretic oxide material in a storage circuit of a memory cell. In some embodiments, IC dies, systems, circuits, and techniques are described herein related to TCAM using hysteretic oxides. Embodiments discussed herein provide advantageous TCAM for use in any computational device or context. In some embodiments, the devices or systems are deployed at very low temperatures, such as at or below 0° C. In some embodiments, very low temperature deployment allows for TCAM having semiconductor structures with very small cross-sectional dimensions such as thicknesses in the range of 0.5 to 20 nm with thicknesses of not more than 2 nm being used in some contexts. In some embodiments, the TCAM is implemented in an integrated circuit (IC) die including or coupled to cooling structure operable to remove heat from the IC die to achieve an operating temperature at the very low temperature. As used herein, the term cooling structure, cooler structure, or active cooling structure indicates a device that uses power to provide cooling (e.g., via flow of a coolant, immersion in a coolant, etc.). Notably, the cooling structure, cooler structure, or active cooling structure need not be in operation to be labeled as such. The active cooling structure may be part of the IC die and/or provided separately from the IC die. In some contexts, an active cooling structure is not needed as the IC die is deployed in a very low temperature environment such as in any of a subpolar oceanic climate, a subarctic climate, an arctic climate, a tundra climate, an ice cap climate, or any other environment of sustained cold temperatures. In some embodiments, the discussed TCAM is implemented in room temperature (or room temperature devices) without use of such cooling structures (although typical cooling techniques such as heat sinks may be used).

In some embodiments, a TCAM includes a number of vertically aligned semiconductor structures. As used herein, the term semiconductor structure indicates a structure of semiconductor material and is inclusive of nanowires or nanoribbons, nanosheets, or fins. Each semiconductor structure includes a channel coupled to and controllable by a gate. The channel is coupled to a source and a drain. The TCAM further includes a corresponding number of independent gate structures (i.e., a gate structure for each semiconductor structure) such that each gate structure is coupled to a corresponding one of the semiconductor structures. The gate structures may be shared across laterally aligned ones of semiconductor structures in different sets of semiconductor structures to form word lines, for example. As used herein, the term gate structure indicates an electrode coupled to a channel of a semiconductor structure and is inclusive of gate structures including a gate dielectric on the semiconductor structure and a gate electrode on the gate dielectric. For example, the TCAM may couple a hysteretic oxide memory cell (HOMC) to a word line, a search line, and a match line, as described further herein below. In some embodiments, the TCAM includes an array of two ferroelectric field effect transistor (2 FeFET) memory cells. Such TCAM is compact and efficient, and other advantages will be evident based on the following disclosure. In addition, such TCAM may utilize multiple hysteretic oxide cells in parallel and/or shared contacts within the hysteretic oxide cells. Such embodiments are discussed further herein below.

As discussed, an IC die including TCAM using hysteretic oxides may be deployed in a very low temperature context. In some embodiments, the operating temperature of the IC die is maintained at or below 0° C. In some embodiments, the operating temperature of the IC die is maintained at or below about −196° C. (i.e., using liquid nitrogen as the coolant). In some embodiments, the operating temperature of the IC die is maintained at or below about −25° C. In some embodiments, the operating temperature of the IC die is maintained at or below about −50° C. In some embodiments, the operating temperature of the IC die is maintained at or below about −70° C. In some embodiments, the IC die is maintained at or below about −100° C. Other temperatures may be used based on coolant, environment, and so on. In operation at such very low temperatures, the TCAM may see a substantial boost in performance relative to operation at higher temperatures inclusive of increased carrier mobility, reduced contact resistance, and reduced leakage. Furthermore, such very low temperature deployment may allow for reduced semiconductor structure size and further TCAM efficiency.

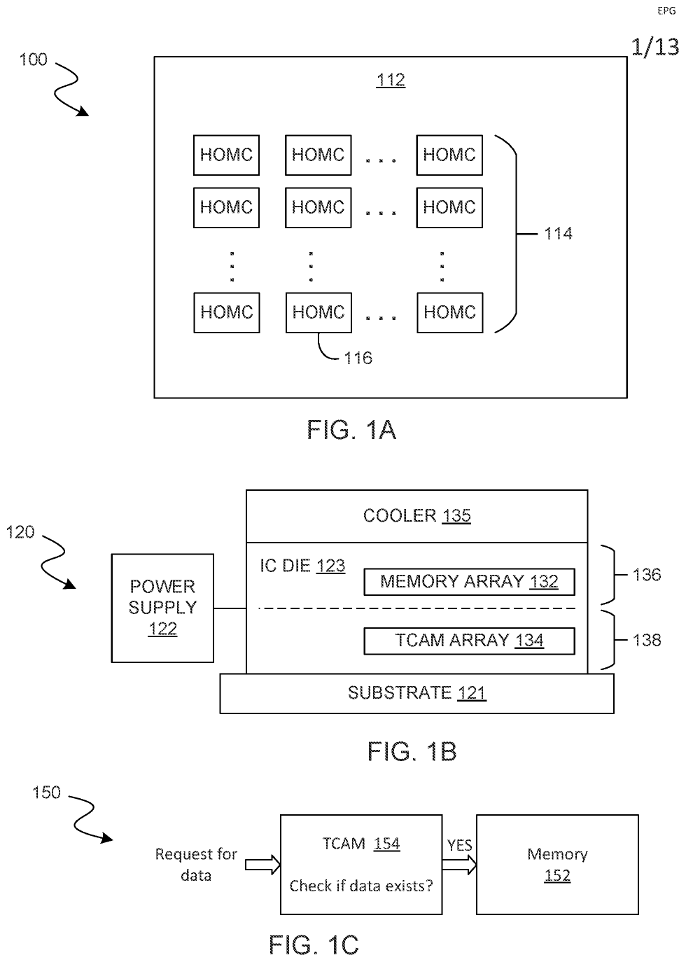

FIG. 1A shows an illustrative plan view of an example integrated circuit (IC) 100 that includes a HOMC in accordance with some embodiments. The IC die 100 includes a substrate 112, and an array of memory cells 114 formed in or on the substrate 112 with a memory cell 116 of the array of memory cells 114 that includes a storage circuit that comprises a hysteretic-oxide material. In some embodiments, the array of memory cells 114 may include two or more hysteric-oxide memory cells coupled in parallel. In some embodiments, the array of memory cells 114 may be configured as a TCAM. In some embodiments, the IC die 100 may further include front-side circuitry (not shown) formed in or on a front-side of the substrate 112, and the TCAM array 114 may be formed in or on a back-side of the substrate 112. The front-side circuitry may include front-side memory, for example, and the TCAM array 114 may be associated with the front-side memory.

In some embodiments, the memory cell 116 may further comprises a first ferroelectric field effect transistor (FeFET) and a second FeFET, where a source terminal of the first FeFET is coupled to a source terminal of the second FeFET, a drain terminal of the first FeFET is coupled to a drain terminal of the second FeFET, and respective gates of the first and second FeFETs include the hysteretic-oxide material (e.g., as described in further detail herein). For example, the first FeFET may programmed at a first voltage threshold (Vt1) and the second FeFET is programmed at a second voltage threshold (Vt2) that is different from Vt1. In some embodiments, at least one of the respectively coupled source and drain terminals of the first and second FeFETs share a contact formed on the substrate 112.

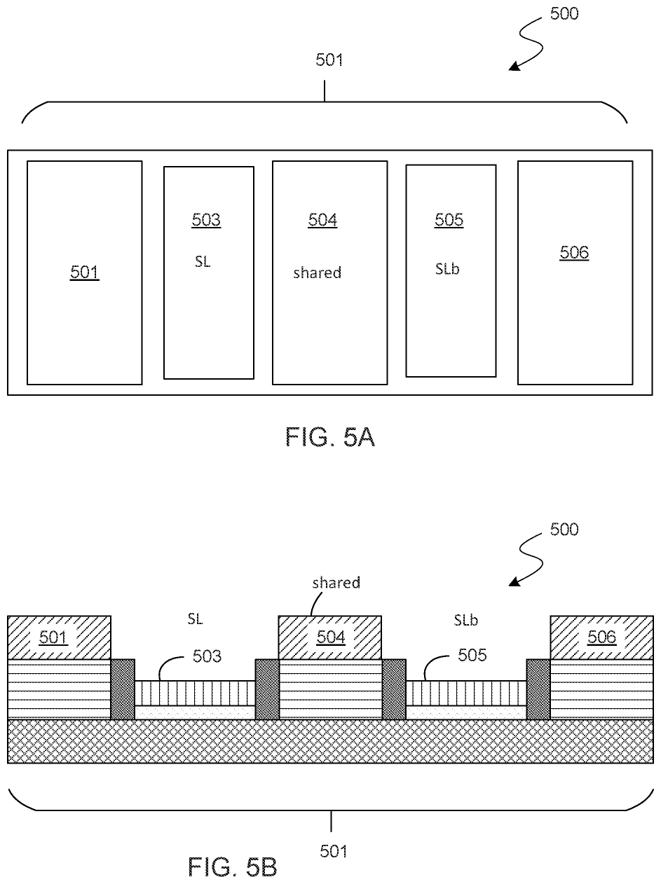

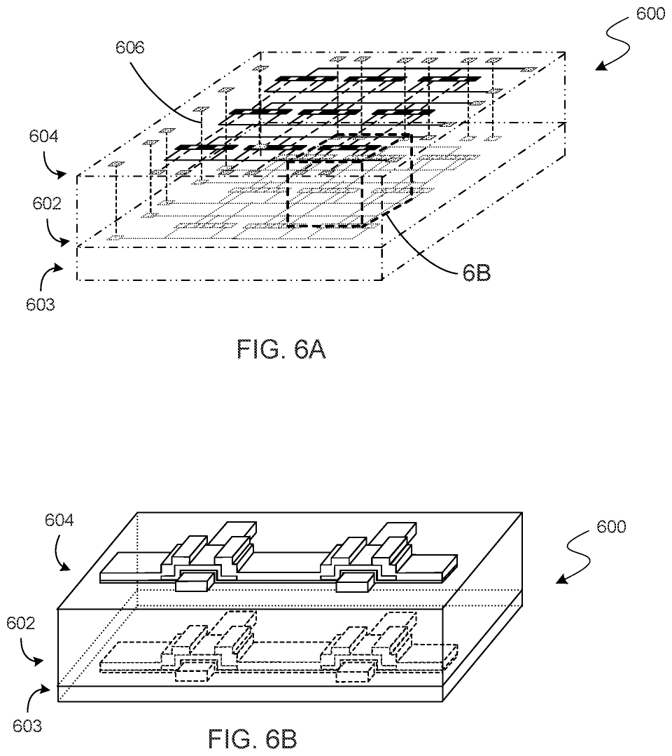

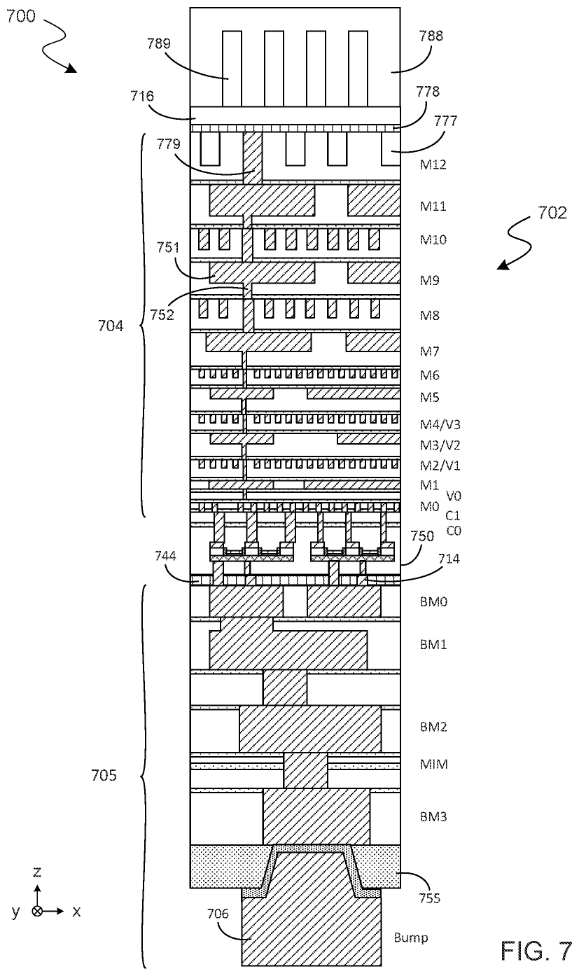

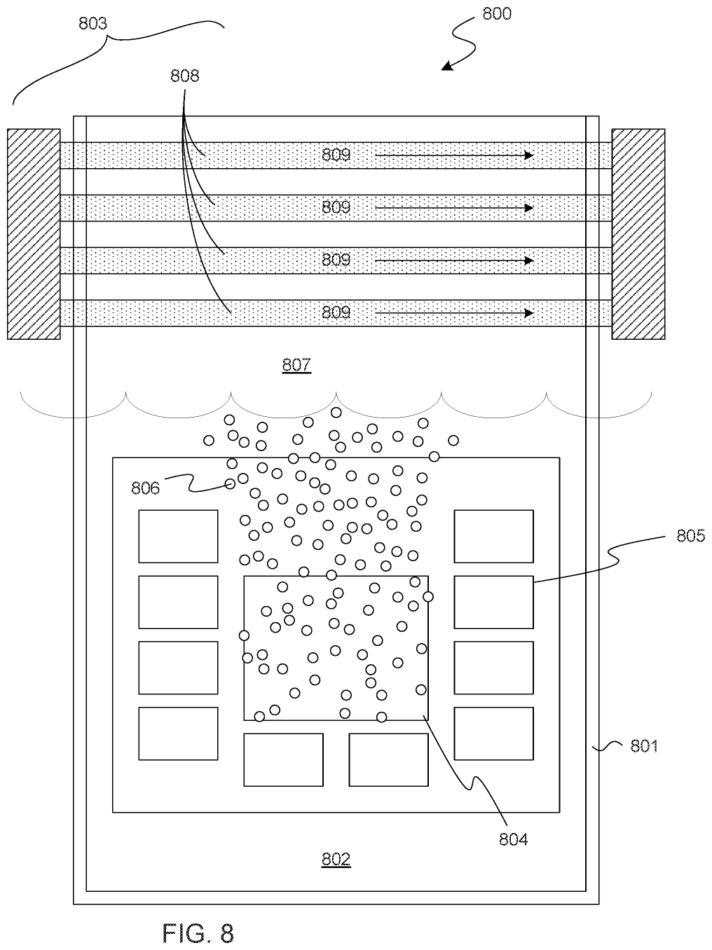

FIG. 1B shows a block diagram view of an example of a system 120 that includes a substrate 121, a power supply 122, and an IC die 123 attached to the substrate 121 and coupled to the power supply 122. The IC die 123 may be similarly configured as any of the various ICs described herein including, for example, the IC die 100 (FIG. 1A), the IC die 500 (FIGS. 5A-B), the IC die 600 (FIGS. 6A-B), and IC die 702 (FIG. 7). Any suitable substrate technology may be utilized for the substrate 121 including, for example, the substrates described herein in connection with FIGS. 7 and 8 (e.g., substrate 805). In some embodiments, the IC die 123 may be coupled to the power supply 122 through the substrate 121.

In some embodiments, the IC die 123 may include a first memory array 132 and a TCAM array 134 associated with the first memory array 132, where the TCAM array 134 includes two or more hysteric-oxide memory cells. In some embodiments, at least two of the two or more hysteric-oxide memory cells are coupled in parallel, and/or the first memory array 132 may be formed in front-side metallization layers 136 of the IC die 123 while the TCAM array 134 may be formed in back-side metallization layers 138 of the IC die 123. In some embodiments, the system 120 may further include a cooler structure 135 thermally coupled to the IC die 123. The cooler structure 135 may be operable to remove heat from the IC die 123 to achieve an operating temperature at or below −25° C.

FIG. 1C illustrates an example block diagram and process flow for a system 150 that includes memory 152 and TCAM 154 associated with the memory 152. Initially, there is a request for data at the TCAM 154. The TCAM 154 checks if the data exists and, if so, provides the request for the data to the memory 152.

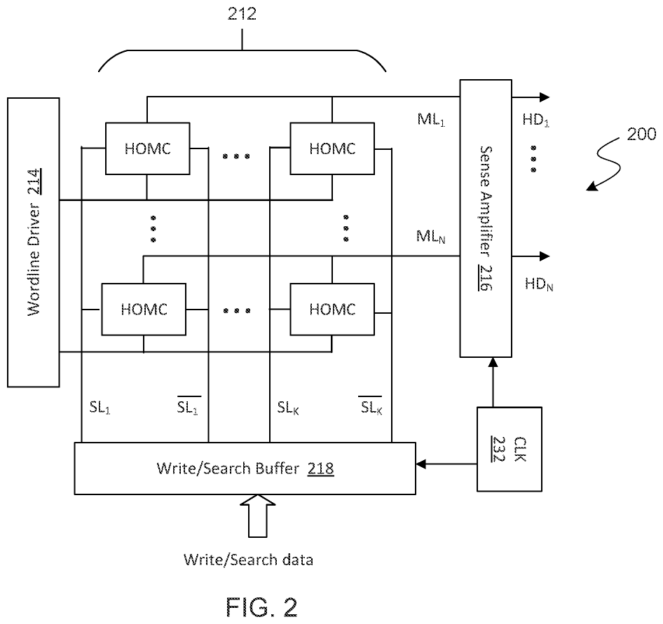

FIG. 2 illustrates an example TCAM 200 that includes an HOMC array 212, wordline driver circuitry 214, a sense amplifier circuitry 216, a write/search buffer 218, and a clock circuit (CLK) 232, coupled as shown. Write/search data is stored in the write/search buffer 218. Based on the data stored in the buffer 218, signals for the search lines SL_{1-K} and SLb_{1-K} ((search line bar 1-K, illustrated with a bar above the signal name) are applied to the HOMC array 212. The wordline driver 214 then applies wordline signals to the HOMC array 212 and the resulting match line signals ML_{1-N} are provided to the sense amplifier 216. The sense amplifier outputs corresponding hit data signals HD_{1-N} that indicate where the data may be present in the TCAM 200.

In some embodiments of a TCAM using hysteretic oxides, the gate of the transistor(s) in the memory cell may have either a ferroelectric layer or charge trapping layer that comprises hysteretic oxide material. Non-limiting examples of suitable hysteretic oxide material include hafnium zirconium oxide, hafnium scandium oxide, hafnium lanthanum oxide, other hafnium oxide-based ferroelectrics, lead-based ferroelectrics, charge strapping oxides, and charge strapping nitrides (e.g., silicon oxide-nitride stacks that store charge). With a suitable hysteretic oxide material, the Vt of the devices is configurable or programmable. By polarizing the devices either positive or negative, the Vt of the transistors may be effectively changed and a suitable Vt difference may be configured/programmed to provide a storage circuit for a memory cell (e.g., with the two different Vts, the circuit can sense whether a given piece of data exists in the memory array or not). Any suitable topology may be utilized for the memory cells. In some embodiments, the device topology for each of the transistors is an individual transistor fabricated with FinFET, planar, nanowire or stacked nanowire, nanoribbon, or nanosheet techniques. In some embodiments, the devices may have a shared contact that advantageously save device area.

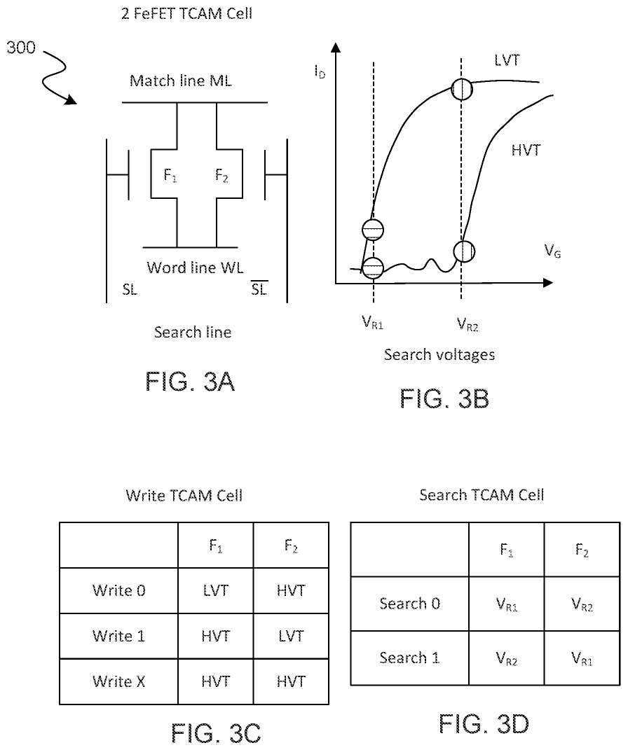

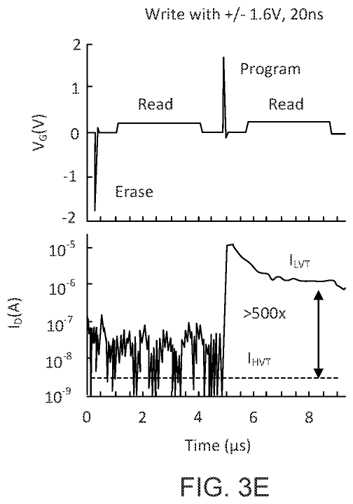

FIG. 3A shows an example HOMC 300 that includes two FeFETs F1 and F2, coupled in parallel as shown. FIG. 3B shows how the two devices F1 and F2 may be programmed with either a low Vt (LVT) or a high Vt (HVT), depending on whether the devices are polarized either positive or negative, and searched with two references VR1 and VR2. FIG. 3C shows how a desired value (0, 1, or X) may be written to the HOMC 300 with the indicated voltages applied to F1 and F2. FIG. 3D shows how the HOMC 300 may be searched with the indicated reference voltages applied to F1 and F2. FIG. 3E shows an example write operation where data is first erased, then read, then programmed, and then read.

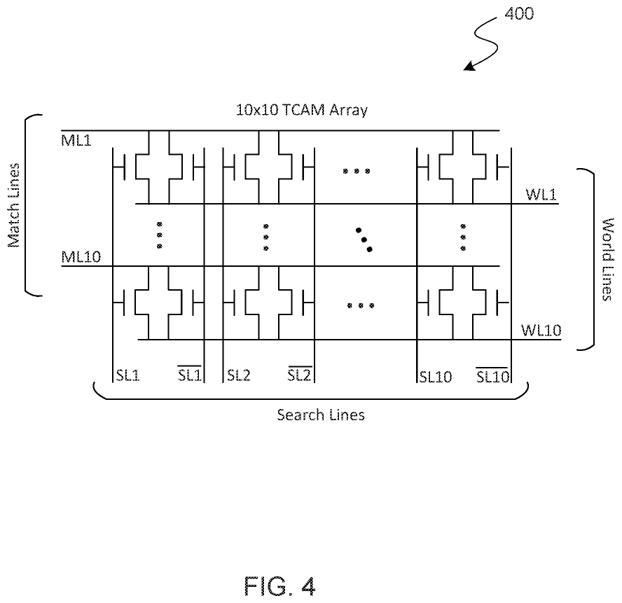

FIG. 4 shows an example TCAM array 400 with a ten-by-ten (10×10) array of two-FeFET HOMCs, coupled as shown. For example, the TCAM array 400 may be implemented for the HOMC array 212 in the TCAM 200 (FIG. 2). The TCAM array 400 stores bits to provide a particular function, generally as an auxiliary circuit or a helper to an associated memory array. For example, the TCAM array 400 may be configured to receive a bitstream of ones and zeros and check if that pattern of ones and zeros exists in the associated memory array. Input data may be put on the search lines. Depending on whether that data exists or not the transistors in the TCAM array 400 will be turned on completely or not turned on. If the transistors are completely turned on, then the corresponding match lines will have some current. If the current exceeds a certain value, then the entire bitstream is available in the associated memory. In some implementations, one wordline at a time may be activated and checked for a match. In some implementations, all of the word lines may be activated and the match line that has the highest current indicates where the data is available.

FIGS. 5A and 5B illustrate an IC die 500 with an example physical implementation of an example HOMC 501. The HOMC 501 includes a first contact 502 (e.g., a source or drain terminal), immediately adjacent to a first gate 503, immediately adjacent to a second contact 504, immediately adjacent to a second gate 505, immediately adjacent to a third contact 506. The second contact 504 is shared between the two gates 503 and 505. Typically, two transistors may be fabricated as contact-gate-contact adjacent to some space and then the next contact-gate-contact. Some embodiments utilize the shared second contact 504 to eliminate the space between the two transistors and one of the transistor contacts, advantageously reducing area.

FIGS. 6A and 6B illustrate an example IC die 600 that includes two or more tiers of TCAM arrays of two-FeFET HOMCs. A Tier-1 TCAM array 602 may be formed on a substrate 603. A Tier-2 TCAM array 604 may be formed over the Tier-1 TCAM array 602 (e.g., with suitable dielectric layer(s) therebetween). Vertical metallization structures or vias 606 may provide appropriate connections between the two TCAM arrays 602 and 604. Although only two tiers are illustrated, the IC die 600 may include more than two tiers with additional vertical metallization structures or vias providing appropriate connections between the multiple tiers of TCAM arrays. Any suitable techniques may be utilized to fabricate the tiers of TCAM arrays of HOMC two-FeFET HOMCs.

In some embodiments, ICs with HOMCs may be integrated into a low-temperature system. Lower temperatures enhance conduction in many materials and can enable the use of, e.g., different materials and structures (such as smaller transistor channels). A number of structures may be used to lower the system temperature and so allow for the use of, e.g., smaller conducting structures. Active cooling structures can be used to lower system temperatures to below ambient temperature, even to well below ambient temperature. Active cooling structures can include thermoelectric coolers. In some embodiments, active cooling structures include stacks of alternating p- and n-type semiconductor materials. In some embodiments, active cooling structures flow cooling fluids through channels, including microchannels, thermally coupled to IC packages. In some embodiments, active cooling structures include channels thermally coupled to IC dies 100. In some embodiments, active cooling structures include channels on one or more sides of IC dies 100. In some embodiments, active cooling structures include channels within IC dies 100. In some embodiments, active cooling structures include two-phase cooling. In some embodiments, active cooling structures include low-boiling-point fluids. In some embodiments, active cooling structures include refrigerants as cooling fluids. In some embodiments, active cooling structures lower system temperatures to below 0° C.

Embodiments of a TCAM with an array of HOMCs may be particularly applicable for low-temperature systems. At low temperatures, transistors fabricated with single nanowires may provide sufficient current because the semiconductor mobility improves. For the threshold voltages, the distribution may get better at low temperatures because there is less thermal noise or thermal excitation. With low temperature processes, entire TCAM may be located in the back end between metal layer. In some implementations, the two FeFET memory cell may be fabricated with low temperature deposited transistors thin film transistors. In other implementations, single crystal transistors that are later transferred may be transferred. A very bare bones transistor structure may be utilized to implement the storage circuit at low temperature. Advantageously, a bare bones transistor structure may have higher density, may be much cheaper, and may be implemented in the back end (e.g., and not consume area in the front end).

FIG. 7 illustrates a cross-sectional view of a low-temperature, IC system 700 using die- and package-level active cooling, and includes HOMCs in accordance with some embodiments. In the example of IC system 700, IC die 702 includes active-cooling structures or components as provided by both die-level microchannels 777 and package-level active-cooling structure 788. IC system 700 includes a lateral surface along the x-y plane that may be defined or taken at any vertical position of IC system 700. The lateral surface of the x-y plane is orthogonal to a vertical or build-up dimension as defined by the z-axis. In some embodiments, IC system 700 may be formed from any substrate material suitable for the fabrication of transistor circuitry. In some embodiments, a semiconductor substrate is used to manufacture HOMCs and other transistors and components of IC system 700. The semiconductor substrate may include a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as gallium arsenide. The substrate may also include semiconductor materials, metals, dielectrics, dopants, and other materials commonly found in semiconductor substrates.

In FIG. 7, IC system 700 includes an IC die 702, which is a monolithic IC with HOMC as described herein, including front-side metallization layers 704 (or front-side interconnect layers), and optional back-side metallization layers 705 (or back-side interconnect layers). As shown, IC die 702 may include HOMCs embedded within a dielectric layer 750. (the detailed structure of the HOMCs is omitted from the cross-section of FIG. 7 to avoid obscuring the figure). In some embodiments, front-side metallization layers 704 (including further HOMCs) provide signal routing to the non-planar transistors and back-side metallization layers 705 provide power delivery, as enabled by through-contacts 714, and vias. In some embodiments, IC system 700 further includes a package-level cooling structure 788, which may be deployed on or over front-side metallization layers 704 (as shown) or on or over a back-side of IC die 702. In some embodiments, package-level cooling structure 788 is coupled to IC die 702 by an adhesion layer 716. IC system 700 may also be deployed without back-side metallization layers 705 shown in FIG. 7. In such embodiments, signal routing and power are provided to circuits of the IC die 702 via front-side metallization layers 704. However, use of back-side metallization layers 705 may offer advantages.

The circuits of the IC die 702 are connected and thermally coupled by metallization, e.g., metal heat spreader 744, to the entire metallization structure by through-contacts 714. In this way, circuits of the IC die 702 are thermally coupled to both the die-level active-cooling structures (of die-level microchannels 777) and package-level active-cooling structure 788.

Interconnectivity of transistors, signal routing to and from circuitry of the IC die 702, vias (e.g., and other vertical metallization structures), etc., power delivery to circuitry of the IC die 702, etc., and routing to an outside device (not shown), is provided by front-side metallization layers 704, optional back-side metallization layers 705, and package-level interconnects 706. In the example of FIG. 7, package-level interconnects 706 are provided on or over a back-side of IC die 702 as bumps over a passivation layer 755, and IC system 700 is attached to substrate (and coupled to signal routing to, power delivery, etc.) by package-level interconnects 706. However, package-level interconnects 706 may be provided using any suitable interconnect structures such as bond pads, solder bumps, etc. Furthermore, in some embodiments, package-level interconnects 706 are provided on or over a front-side of IC die 702 (i.e., over front-side metallization layers 704) and package-level cooling structure 788 is provided on or over a back-side of IC die 702.

In IC system 700, IC die 702 includes die-level, active-cooling as provided by die-level microchannels 777. Die-level microchannels 777 are to convey a heat transfer fluid therein to remove heat from IC die 702. The heat transfer fluid may be any suitable liquid or gas. In some embodiments, the heat transfer fluid is liquid nitrogen operable to lower the temperature of IC die 702 to a temperature at or below about −196° C. In some embodiments, the heat transfer fluid is a fluid with a cryogenic temperature operating window (e.g., about −180° C. to about −70° C.). In some embodiments, the heat transfer fluid is one of helium-3, helium-4, hydrogen, neon, air, fluorine, argon, oxygen, or methane.

As used herein, the term “microchannels” indicates a channel to convey a heat transfer fluid with the multiple microchannels providing discrete separate channels or a network of channels. Notably, the plural microchannels does not indicate separate channel networks are needed. Such die-level microchannels 777 may be provided in any pattern in the x-y plane such as serpentine patterns, patterns of multiple parallel die-level microchannels 777, or the like. Die-level microchannels 777 couple to a heat exchanger (not shown) that removes heat from and cools the heat transfer fluid before re-introduction to die-level microchannels 777. The flow of fluid within die-level microchannels 777 may be provided by a pump or other fluid flow device. The operation of the heat exchanger, pump, etc. may be controlled by a controller.

In the illustrated embodiment, die-level microchannels 777 are implemented at metallization level M12. In other embodiments, die-level microchannels 777 are implemented over metallization level M12. Die-level microchannels 777 may be formed using any suitable technique or techniques such as patterning and etch techniques to form the void structures of die-level microchannels 777 and passivation or deposition techniques to form a cover structure 778 to enclose the void structures. As shown, in some embodiments, the die-level, active-cooling structure of IC system 700 includes a number of die-level microchannels 777 in IC die 702 and over a number of front-side metallization layers 704. As discussed, die-level microchannels 777 are to convey a heat transfer fluid therein. In some embodiments, a metallization feature 779 of metallization layer M12 is laterally adjacent to die-level microchannels 777. For example, metallization feature 779 may couple to a package-level interconnect structure (not shown) for signal routing for IC die 702. In some embodiments, a passive heat removal device such as a heat sink or the like may be used instead of or in addition to package-level cooling structure 788. In some embodiments, package-level cooling structure 788 is not deployed in IC system 700.

As used herein, the term “metallization layer” describes layers with interconnections or wires that provide electrical routing, generally formed of metal or other electrically and thermally conductive material. Adjacent metallization layers may be formed of different materials and by different methods. Adjacent metallization layers, such as metallization interconnects 751, are interconnected by vias, such as vias 752, that may be characterized as part of the metallization layers or between the metallization layers. As shown, in some embodiments, front-side metallization layers 704 are formed over and immediately adjacent transistors. The back-side is then the opposite side, which may be exposed during processing by attaching the front-side to a carrier wafer and exposing the back-side (e.g., by back-side grind or etch operations) as known in the art.

In the illustrated example, front-side metallization layers 704 include M0, V0, M1, M2/V1, M3/V2, M4/V3, and M4-M12. However, front-side metallization layers 704 may include any number of metallization layers such as eight or more metallization layers. Similarly, back-side metallization layers 705 include BM0, BM1, BM2, and BM3. However, back-side metallization layers 705 may include any number of metallization layers such as two to five metallization layers. Front-side metallization layers 704 and back-side metallization layers 705 are embedded within dielectric materials. Furthermore, optional metal-insulator-metal (MIM) devices such as diode devices may be provided within back-side metallization layers 705. Other devices such as memory devices (e.g., that may include HOMCs as described herein) may be provided within front-side metallization layers 704 and/or back-side metallization layers 705.

IC system 700 includes package-level active-cooling structure 788 having package-level microchannels 789. Package-level microchannels 789 are to convey a heat transfer fluid therein to remove heat from IC die 702. The heat transfer fluid may be any suitable liquid or gas as discussed with respect to die-level microchannels 777. Package-level microchannels 789 may be provided in any pattern in the x-y plane such as serpentine patterns, patterns of multiple parallel package-level microchannels 789, etc. Package-level microchannels 789 couple to a heat exchanger (not shown) that removes heat from and cools the heat transfer fluid before re-introduction to package-level microchannels 789. The flow of fluid within package-level microchannels 789 may be provided by a pump or other fluid-flow device. The operation of the heat exchanger, pump, etc. may be controlled by a controller. In the illustrated embodiment, package-level active-cooling structure 788 is a chiller mounted to IC die 702 such that the chiller has a solid body having microchannels therein to convey a heat transfer fluid.

In some embodiments, the heat-removal fluid deployed in die-level microchannels 777 and package-level active-cooling structure 788 are coupled to the same pump and heat exchanger systems. In such embodiments, the heat removal fluid conveyed in both die-level microchannels 777 and package-level active-cooling structure 788 are the same material. Such embodiments may advantageously provide simplicity. In other embodiments, the heat removal fluids are controlled separately. In such embodiments, the heat removal fluids conveyed by die-level microchannels 777 and package-level active-cooling structure 788 may be the same or they may be different. Such embodiments may advantageously provide improved flexibility.

As discussed, IC system 700 includes IC die 702 and optional die-level and package-level active-cooling structures operable to remove heat from IC die 702 to achieve a very low operating temperature of IC die 702. As used herein, the term “very low operating temperature” indicates a temperature at or below 0° C., although even lower temperatures such as an operating temperature at or below −50° C., an operating temperature at or below −70° C., an operating temperature at or below −100° C., an operating temperature at or below −180° C., or an operating temperature at or below −196° C. may be used. In some embodiments, the operating temperature is in a cryogenic temperature operating window (e.g., about −180° C. to about −70° C.). The active-cooling structure may be provided as a package-level structure (i.e., separable from IC die 702), as a die-level structure (i.e., integral to IC die 702), or both. In some embodiments, IC die 702 is deployed in a cold environment, formed using sufficiently conductive materials, etc. and an active-cooling structure is not used.

FIG. 8 illustrates a view of an example two-phase immersion cooling system 800 for low-temperature operation of an IC die with HOMCs, in accordance with some embodiments. As shown, two-phase immersion cooling system 800 includes a fluid containment structure 801, a low-boiling point liquid 802 within fluid containment structure 801, and a condensation structure 803 at least partially within fluid containment structure 801. As used herein, the term “low-boiling point liquid” indicates a liquid having a boiling point in the very low temperature ranges discussed. In some embodiments, the low-boiling point liquid is one of helium-3, helium-4, hydrogen, neon, air, fluorine, argon, oxygen, or methane.

In operation, a heat generation source 804, such as an IC package including any of IC dies, TCAMs, HOMCs, or systems 100, 200, 300, 400, 500, 600, 700 as discussed herein is immersed in low-boiling point liquid 802. In some embodiments, IC dies, TCAMs, HOMCs, or systems 100, 200, 300, 400, 500, 600, 700 as deployed in two-phase immersion cooling system 800 do not include additional active cooling structures, although such die-level or package-level active cooling structures may be used in concert with two-phase immersion cooling system 800. In some embodiments, when deployed in two-phase immersion cooling system 800, package-level active-cooling structure 788 is a heat sink, a heat dissipation plate, a porous heat dissipation plate or the like.

Notably, IC die 702 (or IC die 100, 500, 600), is the source of heat in the context of two-phase immersion cooling system 800. For example, IC die 702 may be packaged and mounted on electronics substrate 805. Electronic substrate 805 may be coupled to a power supply (not shown) and may be partially or completely submerged in low-boiling point liquid 802.

In operation, the heat produced by heat generation source 804 vaporizes low-boiling point liquid 802 as shown in vapor or gas state as bubbles 806, which may collect, due to gravitational forces, above low-boiling point liquid 802 as a vapor portion 807 within fluid containment structure 801. Condensation structure 803 may extend through vapor portion 807. In some embodiments, condensation structure 803 is a heat exchanger having a number of tubes 808 with a cooling fluid (i.e., a fluid colder than the condensation point of vapor portion 807) shown by arrows 809 that may flow through tubes 808 to condense vapor portion 807 back to low-boiling point liquid 802. In the IC system of FIG. 8, package-level active-cooling structure 788 includes a passive cooling structure such as a heat sink for immersion in low-boiling point liquid 802.

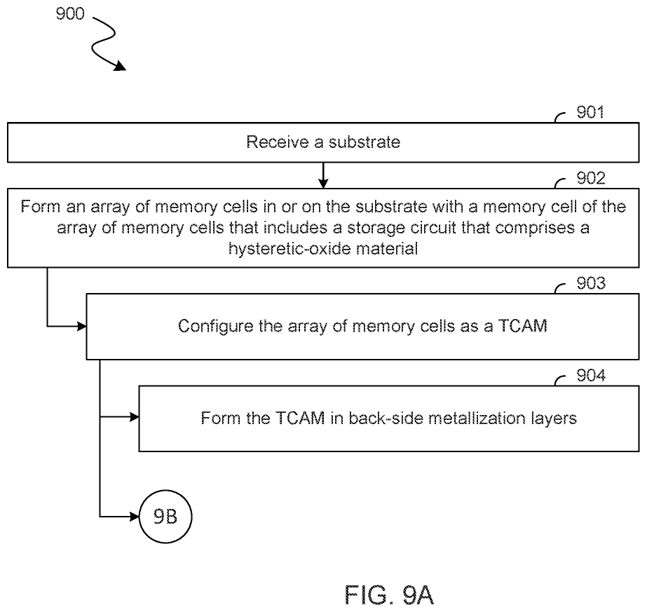

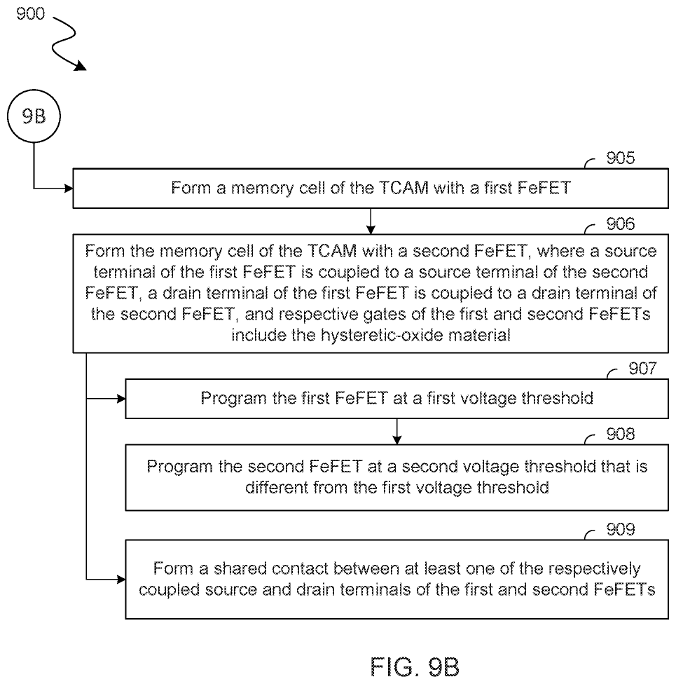

FIGS. 9A to 9B illustrate various processes or methods 900 for forming memory cells using hysteretic oxides on an IC die, in accordance with some embodiments. FIGS. 9A to 9B show methods 900 that includes operations 901-909. Some operations shown in FIGS. 9A to 9B are optional. FIGS. 9A to 9B show an example sequence, but the operations can be done in other sequences as well, and some operations may be omitted. Some operations can also be performed multiple times before other operations are performed. Some operations may be included within other operations. Methods 900 generally entail forming an array of memory cells in or on a substrate with a memory cell of the array of memory cells that includes a storage circuit that comprises a hysteretic-oxide material.

In operation 901, a substrate is received. The substrate is a planar platform and may already include dielectric and metallization structures. The substrate may be one of many layers in an IC die, and may itself have many layers. The substrate may be above other layers in the IC die (all or of a portion of which may be subsequently removed in back-side metallization contexts), and other layers may subsequently be formed in or over the substrate. In some embodiments, HOMCs will be formed on a frontside of the substrate. In some embodiments, HOMCs will be formed on a backside. In some embodiments, HOMCs will be formed on both sides.

The substrate may include any suitable material or materials. Any suitable semiconductor or other material can be used. Transistors in the IC die may be of the same material as the substrate or, e.g., deposited on the substrate. The substrate may include a semiconductor material that transistors can be formed out of and on, including a crystalline material. In some examples, the substrate may include monocrystalline silicon (Si), germanium (Ge), silicon germanium (SiGe), a III-V alloy material (e.g., gallium arsenide (GaAs)), a silicon carbide (SiC), a sapphire (Al2O3), or any combination thereof. In some embodiments, the substrate includes crystalline silicon and subsequent components are also silicon.

In operation 902, an array of memory cells is formed in or on the substrate with a memory cell of the array of memory cells that includes a storage circuit that comprises a hysteretic-oxide material. The array need not be formed before, e.g., other layers of the IC die. Forming the array and other layers of the IC die may include forming transistors, resistors, and interconnections, e.g., between them and with external structures, including power, signal, data, ground, etc. lines. At least some of these structures may be conventional and known methods may be used.

Transistors in the array can be formed from the same material as the substrate or, e.g., deposited on the substrate. In some embodiments, the substrate is crystalline silicon and transistors in the first layer are formed by etching back the substrate to form transistor structures, e.g., non-planar structures, such as fins for access transistor channels. In some embodiments, transistors comprise polycrystalline silicon, which may be deposited over other materials. Other semiconductor materials may be deposited as well, on the substrate or over other structures on the substrate. Such semiconductor materials can be any material suitable for forming a transistor channel, e.g., for an access transistor, but some materials will be preferred for their manufacturing properties, e.g., the capability to be deposited easily, in a well-controlled manner, and in thin layers.

Forming the array of memory cells may include forming ultrathin structures, such as nanowires, nanoribbons, or nanosheets, for transistor channels. In some embodiments, one or a few monolayers of semiconductor materials are deposited over the substrate or other structures. In some embodiments, less than 2 nm of semiconductor material is deposited as a film. In some embodiments, a transition-metal dichalcogenide (TMD) material is deposited to form access transistors. TMDs can be 2D materials, e.g., forming monolayers of semiconductor materials. 2D materials may be deposited on structures, such as backbone features, deposited on the substrate.

The methods for forming transistors may vary with transistor function. TFTs for use as pull-up transistors may be formed as parasitic devices deposited over other structures in some layers. In some embodiments, forming transistors includes depositing amorphous or polycrystalline metal oxides. In some embodiments, a thin, metal-oxide film is deposited that may be semiconducting substantially as-deposited, and/or following some subsequent activation process, such as a thermal anneal.

Other structures, e.g., resistors and metallization, may also be deposited or otherwise formed from such materials, and such forming may be done throughout the forming operations of transistors and other structures. Pull-up resistors may be formed from the substrate material or, e.g., by depositing polycrystalline silicon or other material over the substrate. Other structures, e.g., access transistor gate electrodes, may be formed such that convenient connections can be made to associated structures in the first layer. Metallization may be formed before and after, and interleaved throughout, the forming of other structures.

In operation 903, the array of memory cells is configured as a TCAM. In operation 904, the TCAM is formed in back-side metallization layers. In operation 905, a memory cell of the TCAM is formed with a first FeFET and, at operation 906, the memory cell of the TCAM with is formed with a second FeFET, where a source terminal of the first FeFET is coupled to a source terminal of the second FeFET, a drain terminal of the first FeFET is coupled to a drain terminal of the second FeFET, and respective gates of the first and second FeFETs include the hysteretic-oxide material. At operations 907 and 908, the first FeFET is programmed at a first voltage threshold and the second FeFET is programmed at a second voltage threshold that is different from the first voltage threshold. At operation 909, a shared contact is formed between at least one of the respectively coupled source and drain terminals of the first and second FeFETs.

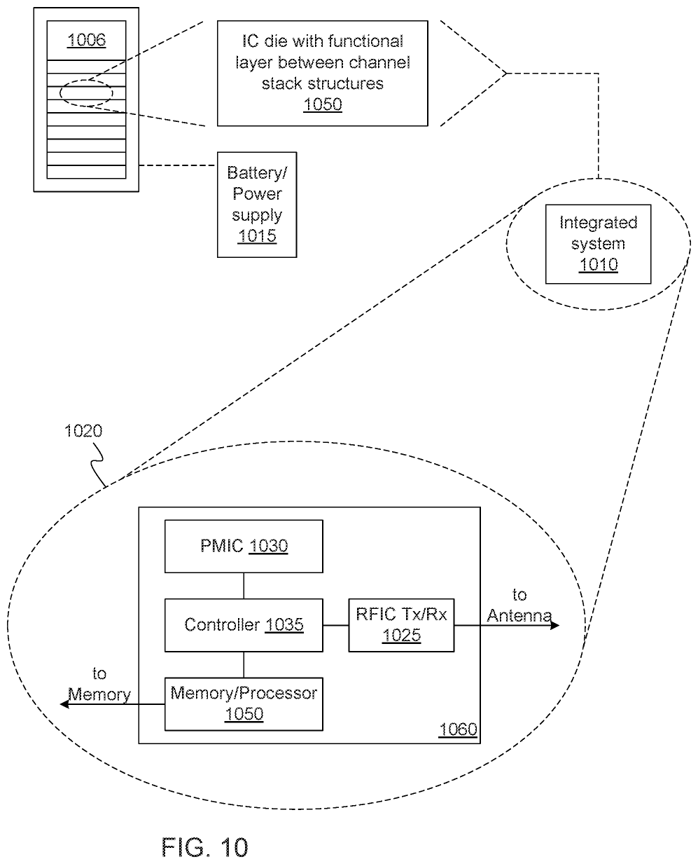

FIG. 10 illustrates a diagram of an example data server machine 1006 employing an IC die with HOMCs, in accordance with some embodiments. Server machine 1006 may be any commercial server, for example, including any number of high-performance computing platforms disposed within a rack and networked together for electronic data processing, which in the exemplary embodiment includes one or more devices 1050 having HOMCs.

Also as shown, server machine 1006 includes a battery and/or power supply 1015 to provide power to devices 1050, and to provide, in some embodiments, power delivery functions such as power regulation. Devices 1050 may be deployed as part of a package-level integrated system 1010. Integrated system 1010 is further illustrated in the expanded view 1020. In the exemplary embodiment, devices 1050 (labeled “Memory/Processor”) includes at least one memory chip (e.g., RAM), and/or at least one processor chip (e.g., a microprocessor, a multi-core microprocessor, or graphics processor, or the like) having the characteristics discussed herein. In an embodiment, device 1050 is a microprocessor including a cache memory. As shown, device 1050 may be a multi-chip module employing one or more IC dies with HOMCs, as discussed herein. Device 1050 may be further coupled to (e.g., communicatively coupled to) a board, an interposer, or a substrate 1060 along with, one or more of a power management IC (PMIC) 1030, RF (wireless) IC (RFIC) 1025, including a wideband RF (wireless) transmitter and/or receiver (TX/RX) (e.g., including a digital baseband and an analog front end module further comprises a power amplifier on a transmit path and a low noise amplifier on a receive path), and a controller 1035 thereof. In some embodiments, RFIC 1025, PMIC 1030, controller 1035, and device 1050 include IC dies having HOMCs on substrate 1060 in a multi-chip module.

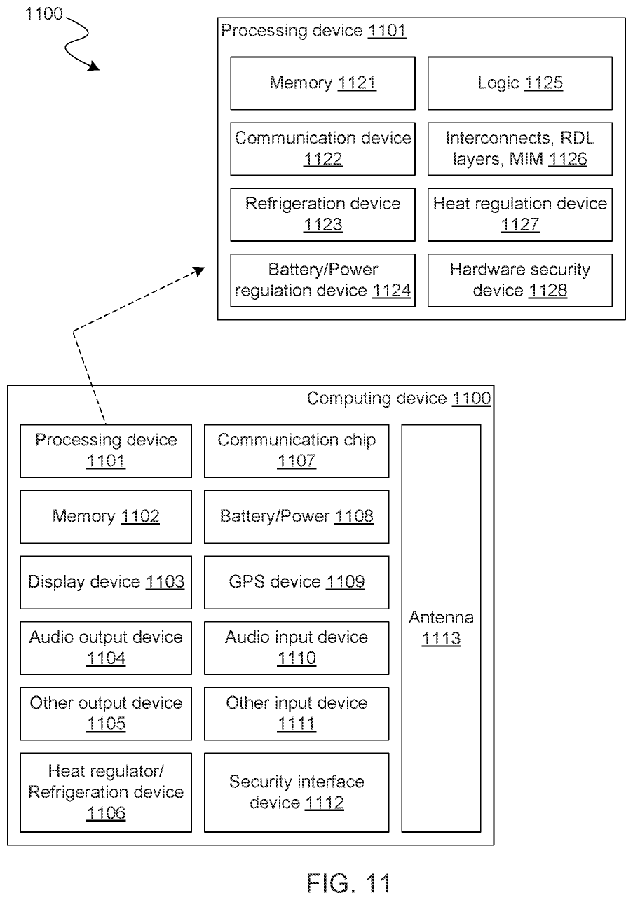

FIG. 11 is a block diagram of an example computing device 1100, in accordance with some embodiments. For example, one or more components of computing device 1100 may include any of the devices or structures discussed herein. A number of components are illustrated in FIG. 11 as being included in computing device 1100, but any one or more of these components may be omitted or duplicated, as suitable for the application. In some embodiments, some or all of the components included in computing device 1100 may be attached to one or more printed circuit boards (e.g., a motherboard). In some embodiments, various ones of these components may be fabricated onto a single system-on-a-chip (SoC) die. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled. In another set of examples, computing device 1100 may not include an audio output device 1104, other output device 1105, global positioning system (GPS) device 1109, audio input device 1110, or other input device 1111, but may include audio output device interface circuitry, other output device interface circuitry, GPS device interface circuitry, audio input device interface circuitry, audio input device interface circuitry, to which audio output device 1104, other output device 1105, GPS device 1109, audio input device 1110, or other input device 1111 may be coupled.

Computing device 1100 may include a processing device 1101 (e.g., one or more processing devices). As used herein, the term “processing device” or “processor” indicates a device that processes electronic data from registers and/or memory to transform that electronic data into other electronic data that may be stored in registers and/or memory. Processing device 1101 may include a memory 1121 (itself including HOMCs), a communication device 1122, a refrigeration device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1100 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1102 includes memory that shares a die with processing device 1101. This memory may be used as cache memory and may include embedded dynamic random-access memory (eDRAM) or spin transfer torque magnetic random-access memory (STT-M RAM).

Computing device 1100 may include a heat regulation/refrigeration device 1106. Heat regulation/refrigeration device 1106 may maintain processing device 1101 (and/or other components of computing device 1100) at a predetermined low temperature during operation. This predetermined low temperature may be any temperature discussed herein.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an antenna 1113 to facilitate wireless communications and/or to receive other wireless communications (such as AM or FM radio transmissions).

In some embodiments, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some embodiments, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a GPS device 1109 (or corresponding interface circuitry, as discussed above). GPS device 1109 may be in communication with a satellite-based system and may receive a location of computing device 1100, as known in the art.

Computing device 1100 may include other output device 1105 (or corresponding interface circuitry, as discussed above). Examples of the other output device 1105 may include an audio codec, a video codec, a printer, a wired or wireless transmitter for providing information to other devices, or an additional storage device.

Computing device 1100 may include other input device 1111 (or corresponding interface circuitry, as discussed above). Examples of the other input device 1111 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, access list management, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-11. The subject matter may be applied to other deposition applications, as well as any appropriate manufacturing application, as will be understood to those skilled in the art.

The following examples pertain to further embodiments, and specifics in the examples may be used anywhere in one or more embodiments.

Example 1 includes an integrated circuit (IC) die, comprising a substrate, and an array of memory cells formed in or on the substrate with a memory cell of the array of memory cells that includes a storage circuit that comprises a hysteretic-oxide material.

Example 2 includes the IC die of Example 1, wherein the array of memory cells includes two or more hysteric-oxide memory cells coupled in parallel.

Example 3 includes the IC die of Example 2, wherein the array of memory cells is configured as a ternary content-addressable memory (TCAM).

Example 4 includes the IC die of Example 3, further comprising a front-side memory formed in or on a front-side of the substrate, wherein the TCAM is associated with the front-side memory and wherein the TCAM is formed in or on a back-side of the substrate.

Example 5 includes the IC die of any of Examples 1 to 4, wherein the memory cell further comprises a first ferroelectric field effect transistor (FeFET), and a second FeFET, wherein a source terminal of the first FeFET is coupled to a source terminal of the second FeFET, a drain terminal of the first FeFET is coupled to a drain terminal of the second FeFET, and respective gates of the first and second FeFETs include the hysteretic-oxide material.

Example 6 includes the IC die of Example 5, wherein the first FeFET is programmed at a first voltage threshold and the second FeFET is programmed at a second voltage threshold that is different from the first voltage threshold.

Example 7 includes the IC die of any of Examples 5 to 6, wherein at least one of the respectively coupled source and drain terminals of the first and second FeFETs share a contact formed on the substrate.

Example 8 includes a system, comprising a substrate, a power supply, and an integrated circuit (IC) die attached to the substrate and coupled to the power supply, the IC die comprising a first memory array, a ternary content-addressable memory (TCAM) array associated with the first memory array, wherein the TCAM array includes two or more hysteric-oxide memory cells.

Example 9 includes the system of Example 8, wherein at least two of the two or more hysteric-oxide memory cells are coupled in parallel.

Example 10 includes the system of any of Examples 8 to 9, wherein the first memory array is formed in front-side metallization layers of the IC die, and wherein the TCAM array is formed in back-side metallization layers of the IC die.

Example 11 includes the system of any of Examples 8 to 10, wherein at least one of the two or more hysteric-oxide memory cells each further comprises a first ferroelectric field effect transistor (FeFET), and a second FeFET, wherein a source terminal of the first FeFET is coupled to a source terminal of the second FeFET, a drain terminal of the first FeFET is coupled to a drain terminal of the second FeFET, and respective gates of the first and second FeFETs include hysteretic-oxide material.

Example 12 includes the system of Example 11, wherein the first FeFET is programmed at a first voltage threshold and the second FeFET is programmed at a second voltage threshold that is different from the first voltage threshold.

Example 13 includes the system of Example 12, wherein at least one of the respectively coupled source and drain terminals of the first and second FeFETs share a contact formed on the substrate.

Example 14 includes the system of any of Examples 8 to 13, further comprising a cooler structure thermally coupled to the IC die and operable to remove heat from the IC die to achieve an operating temperature at or below −25° C.

Example 15 includes a method, comprising receiving a substrate, forming an array of memory cells in or on the substrate with a memory cell of the array of memory cells that includes a storage circuit that comprises a hysteretic-oxide material.

Example 16 includes the method of Example 15, further comprising configuring the array of memory cells as a ternary content-addressable memory (TCAM).

Example 17 includes the method of Example 16, further comprising forming the TCAM in back-side metallization layers.

Example 18 includes the method of any of Examples 16 to 17, further comprising forming a memory cell of the TCAM with a first ferroelectric field effect transistor (FeFET), and forming the memory cell of the TCAM with a second FeFET, wherein a source terminal of the first FeFET is coupled to a source terminal of the second FeFET, a drain terminal of the first FeFET is coupled to a drain terminal of the second FeFET, and respective gates of the first and second FeFETs include the hysteretic-oxide material.

Example 19 includes the method of Example 18, further comprising programming the first FeFET at a first voltage threshold, and programming the second FeFET at a second voltage threshold that is different from the first voltage threshold.

Example 20 includes the method of any of Examples 18 to 19, further comprising forming a shared contact between at least one of the respectively coupled source and drain terminals of the first and second FeFETs.

Example 21 includes an apparatus, comprising means for receiving a substrate, means for forming an array of memory cells in or on the substrate with a memory cell of the array of memory cells that includes a storage circuit that comprises a hysteretic-oxide material.

Example 22 includes the apparatus of Example 21, further comprising means for configuring the array of memory cells as a ternary content-addressable memory (TCAM).

Example 23 includes the apparatus of Example 22, further comprising means for forming the TCAM in back-side metallization layers.

Example 24 includes the apparatus of any of Examples 22 to 23, further comprising means for forming a memory cell of the TCAM with a first ferroelectric field effect transistor (FeFET), and means for forming the memory cell of the TCAM with a second FeFET, wherein a source terminal of the first FeFET is coupled to a source terminal of the second FeFET, a drain terminal of the first FeFET is coupled to a drain terminal of the second FeFET, and respective gates of the first and second FeFETs include the hysteretic-oxide material.

Example 25 includes the apparatus of Example 24, further comprising means for programming the first FeFET at a first voltage threshold, and means for programming the second FeFET at a second voltage threshold that is different from the first voltage threshold.

Example 26 includes the apparatus of any of Examples 24 to 25, further comprising means for forming a shared contact between at least one of the respectively coupled source and drain terminals of the first and second FeFETs.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An integrated circuit (IC) die, comprising:
a substrate; and
an array of memory cells formed in or on the substrate with a memory cell of the array of memory cells that includes a storage circuit that comprises a hysteretic-oxide material.

2. The IC die of claim 1, wherein the array of memory cells includes two or more hysteric-oxide memory cells coupled in parallel.

3. The IC die of claim 2, wherein the array of memory cells is configured as a ternary content-addressable memory (TCAM).

4. The IC die of claim 3, further comprising:
a front-side memory formed in or on a front-side of the substrate, wherein the TCAM is associated with the front-side memory and wherein the TCAM is formed in or on a back-side of the substrate.

5. The IC die of claim 1, wherein the memory cell further comprises:
a first ferroelectric field effect transistor (FeFET); and
a second FeFET, wherein a source terminal of the first FeFET is coupled to a source terminal of the second FeFET, a drain terminal of the first FeFET is coupled to a drain terminal of the second FeFET, and respective gates of the first and second FeFETs include the hysteretic-oxide material.

6. The IC die of claim 5, wherein the first FeFET is programmed at a first voltage threshold and the second FeFET is programmed at a second voltage threshold that is different from the first voltage threshold.

7. The IC die of claim 5, wherein at least one of the respectively coupled source and drain terminals of the first and second FeFETs share a contact formed on the substrate.

8. A system, comprising:
a substrate;
a power supply; and
an integrated circuit (IC) die attached to the substrate and coupled to the power supply, the IC die comprising:
a first memory array;
a ternary content-addressable memory (TCAM) array associated with the first memory array, wherein the TCAM array includes two or more hysteric-oxide memory cells.

9. The system of claim 8, wherein at least two of the two or more hysteric-oxide memory cells are coupled in parallel.

10. The system of claim 8, wherein the first memory array is formed in front-side metallization layers of the IC die, and wherein the TCAM array is formed in back-side metallization layers of the IC die.

11. The system of claim 8, wherein at least one of the two or more hysteric-oxide memory cells each further comprises:
a first ferroelectric field effect transistor (FeFET); and
a second FeFET, wherein a source terminal of the first FeFET is coupled to a source terminal of the second FeFET, a drain terminal of the first FeFET is coupled to a drain terminal of the second FeFET, and respective gates of the first and second FeFETs include hysteretic-oxide material.

12. The system of claim 11, wherein the first FeFET is programmed at a first voltage threshold and the second FeFET is programmed at a second voltage threshold that is different from the first voltage threshold.

13. The system of claim 12, wherein at least one of the respectively coupled source and drain terminals of the first and second FeFETs share a contact formed on the substrate.

14. The system of claim 8, further comprising:
a cooler structure thermally coupled to the IC die and operable to remove heat from the IC die to achieve an operating temperature at or below −25° C.

15. A method, comprising:
receiving a substrate;
forming an array of memory cells in or on the substrate with a memory cell of the array of memory cells that includes a storage circuit that comprises a hysteretic-oxide material.

16. The method of claim 15, further comprising:
configuring the array of memory cells as a ternary content-addressable memory (TCAM).

17. The method of claim 16, further comprising:
forming the TCAM in back-side metallization layers.

18. The method of claim 16, further comprising:
forming a memory cell of the TCAM with a first ferroelectric field effect transistor (FeFET); and
forming the memory cell of the TCAM with a second FeFET, wherein a source terminal of the first FeFET is coupled to a source terminal of the second FeFET, a drain terminal of the first FeFET is coupled to a drain terminal of the second FeFET, and respective gates of the first and second FeFETs include the hysteretic-oxide material.

19. The method of claim 18, further comprising:
programming the first FeFET at a first voltage threshold; and
programming the second FeFET at a second voltage threshold that is different from the first voltage threshold.

20. The method of claim 18, further comprising:
forming a shared contact between at least one of the respectively coupled source and drain terminals of the first and second FeFETs.
